(19) United States
(12) Patent Application Publication
(10) Pub. No.: US 2018/0277692 A1
(43) Pub. Date: Sep. 27, 2018

(54) SOLAR CELL, MULTI-JUNCTION SOLAR CELL, SOLAR CELL MODULE, AND SOLAR POWER GENERATION SYSTEM

(71) Applicant: KABUSHIKI KAISHA TOSHIBA, Tokyo (JP)

(72) Inventors: Miyuki Shiokawa, Kawasaki Kanagawa (JP); Soichiro Shibasaki, Nerima Tokyo (JP); Naoyuki Nakagawa, Setagaya Tokyo (JP); Kazushige Yamamoto, Yokohama Kanagawa (JP)

(21) Appl. No.: 15/704,163

(22) Filed: Sep. 14, 2017

(30) Foreign Application Priority Data
Mar. 23, 2017 (JP) 2017-057677
Sep. 13, 2017 (JP) 2017-175595

(51) Int. Cl. H01L 31/0216; H01L 31/0224

(52) U.S. Cl. CPC H01L 31/02168; H01L 31/0725; H01L 31/022433

(57) ABSTRACT

A solar cell of an embodiment includes a high-resistance oxide layer; a first electrode comprising line-patterned conductive members or mesh-patterned conductive members; a second electrode; and a light absorbing layer between the high-resistance oxide layer and the second electrode. The first electrode is disposed between the high-resistance oxide layer and the light absorbing layer.

### CROSS-REFERENCE TO RELATED APPLICATION

This application is based upon and claims the benefit of priority from Japanese Patent Applications No. 2017-057677, filed on Mar. 23, 2017 and No. 2017-175595, filed on Sep. 13, 2017; the entire contents of which are incorporated herein by reference.

### FIELD

Embodiments described herein relate to a solar cell, a multi-junction solar cell, a solar cell module, and a solar power generation system.

### BACKGROUND

High-efficiency solar cells include multi-junction (tandem) solar cells. Multi-junction solar cells, which can have high-efficiency cells for each wavelength band, are expected to have efficiency higher than that of single-junction solar cells. Chalcopyrite solar cells such as CIGS are known to have high efficiency and thus can be candidates for top cells when designed to have a wide gap. However, if such solar cells are used as top cells, light with energy not higher than the band gap energy should be transmitted. If a transparent electrode is used, oxidation can occur at the interface between the transparent electrode and a light absorbing layer to deteriorate the contact and to make the efficiency less likely to increase.

### BRIEF DESCRIPTION OF THE DRAWINGS

FIG. 1 is a schematic cross-sectional view of a solar cell according to an embodiment;

FIG. 2 is an image diagram of a solar cell according to an embodiment;

FIG. 3 is a schematic perspective view of a solar cell according to an embodiment;

FIG. 4 is a schematic perspective view of a solar cell according to an embodiment;

FIG. 5 is a graph showing the relationship between line gap, line width, and aperture ratio according to an embodiment;

FIG. 6 is a graph showing the relationship between mesh gap, mesh width, and aperture ratio according to an embodiment;

FIG. 7 is a schematic cross-sectional view of a solar cell according to an embodiment;

FIG. 8 is a schematic cross-sectional view of a solar cell according to an embodiment;

FIG. 9 is a schematic cross-sectional view of a multi-junction solar cell according to an embodiment;

FIG. 10 is a schematic diagram of a solar cell module according to an embodiment;

FIGS. 11(a) and 11(b) are schematic plan and cross-sectional views of a solar cell module according to an embodiment;

FIGS. 12(a) and 12(b) are schematic plan and cross-sectional views of a solar cell module according to an embodiment; and

FIG. 13 is a schematic diagram of a solar power generation system according to an embodiment.

### DETAILED DESCRIPTION

A solar cell of an embodiment includes a high-resistance oxide layer; a first electrode including line-patterned conductive members or mesh-patterned conductive members; a second electrode; and a light absorbing layer between the high-resistance oxide layer and the second electrode. The first electrode is disposed between the high-resistance oxide layer and the light absorbing layer.

Hereinafter, embodiments will be described in detail with reference to the drawings.

### First Embodiment

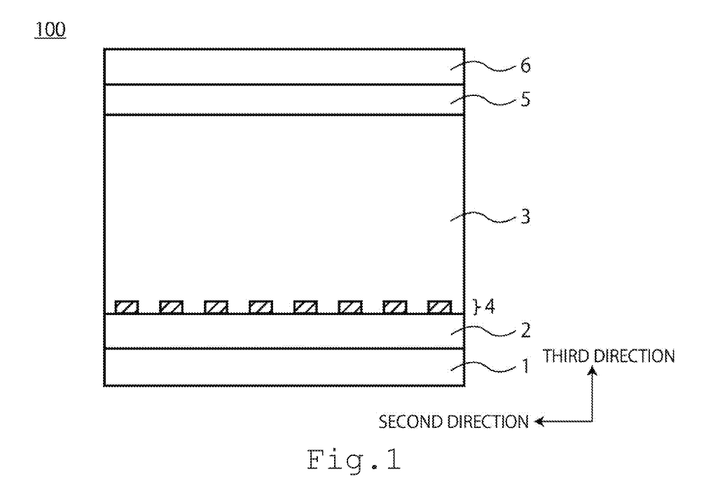

As shown in FIG. 1, a solar cell 100 according to this embodiment includes a substrate 1 and an oxide layer 2 on the substrate 1. A light absorbing layer 3 and an n-type layer 5 are disposed between the oxide layer 2 and a second electrode 6. In addition, the light absorbing layer 3 is disposed between the oxide layer 2 and the n-type layer 5. A line region or mesh region is also provided as a first electrode 4 between the oxide layer 2 and the light absorbing layer 3. FIG. 1 is a cross-sectional view in the second and third directions. The first direction is the depth direction of the cross-section. The first and second directions intersect with each other. The third direction is the stacking direction, which is perpendicular to the first and second directions.

(Substrate)

In this embodiment, the substrate 1 is preferably made of soda-lime glass, but may also be made of quartz, common glass such as white sheet glass or chemically reinforced glass, a sheet of a metal such as stainless steel, titanium (Ti), or chromium (Cr), or a resin such as polyimide or acrylic.

(Oxide Layer)

In this embodiment, the oxide layer 2 has a transmittance higher than that of a transparent electrode with respect to the substrate 1 in the solar cell 100. In a conventional multi-junction solar cell, the light incident side cell has a transparent electrode between the substrate 1 and the light absorbing layer 3. Such a transparent electrode has a relatively high carrier density and thus has a tendency to reflect infrared light with a wavelength of 900 nm or more. If the light incident side cell of a multi-junction solar cell has a transparent electrode with a tendency to reflect infrared light, the intensity of infrared light will decrease as it passes through the light incident side cell so that the amount of power generation by the solar cells located below the light incident side cell will decrease. In order to achieve good contact and high light transmission, a line-patterned electrode or a mesh-patterned electrode should preferably be disposed between the light absorbing layer 3 and the oxide layer 2 on the high-resistance oxide layer 2. SnO₂ with high resistance can provide improved transmittance for light including infrared light (improved average transmittance for light with wavelengths of 700 to 1,150 nm) as compared with a transparent electrode (antimony tin oxide (ATO) or indium tin oxide (ITO)) with low resistance.

The oxide layer 2 is, for example, a transparent, high-resistance (low-conductivity), metal oxide layer formed on the substrate 1. The oxide layer 2 is disposed between the substrate 1 and the light absorbing layer 3. The oxide layer 2 may be a single metal oxide layer including at least a SnO₂ layer or may be a multilayered metal oxide film including at least a SnO₂ layer. In addition to the SnO₂ layer, the multilayered metal oxide film may further include a layer including at least one oxide selected from the group consisting of: InO₂, TiO₂, and ZnO.

Since the oxide layer 2 has high resistance, it does not function as an electrode, and the first electrode 4 having a line-patterned region or mesh-patterned region functions as one electrode of the solar cell. An oxide layer used to form a transparent electrode, such as SnO₂:Sb (antimony tin oxide (ATO)) or SnO₂:F (fluorine-doped tin oxide (FTO) has a carrier density of 3.0 at % or more. Therefore, the oxide layer 2 in this embodiment has a carrier density different from that of the conductive oxide layer called ATO or FTO. The oxide layer 2 should be obtained as a transparent insulating layer with high resistance and high infrared transparency. For this purpose, the oxide layer 2 should preferably be free of a Sb or F dopant serving as a carrier or preferably has a low Sb or F dopant concentration. In view of infrared transparency, the total content of Sb and F dopants in the oxide layer 2 is preferably 0.0 at % to 2.8 at %, more preferably 0.0 at % to 2.5 at %, even more preferably 0.0 at % to 2.0 at %. In view of infrared transparency, the total content of Sb and F dopants in any one metal oxide layer constituting the oxide layer 2 is preferably 0.0 at % to 2.8 at %. In this embodiment, the total content of Sb and F dopants in the oxide layer 2 is lower than that of a low-resistance oxide layer capable of functioning as a transparent electrode. In some cases, the oxide layer 2 contains, as impurities, elements other than Sn, In, Ti, Zn, Sb, F, and O. Such impurities can reduce the infrared transmittance, and some of them can reduce the resistance of the oxide. Therefore, the solar cell of this embodiment having the first electrode 4 is preferably as free as possible of such impurities. The total concentration of impurities in the oxide layer 2 is preferably 1.0 at % or less, more preferably 0.5 at % or less. SnO₂ can provide improved infrared transmittance as compared with transparent electrodes (ATO, FTO, ITO). For example, the oxide layer 2 according to this embodiment does not include any oxide layer capable of functioning as a transparent electrode, such as indium-tin oxide (ITO), or ZnO:Ga or ZnO:Al, which is doped with a carrier, because such an oxide layer has either low resistance or low infrared transparency.

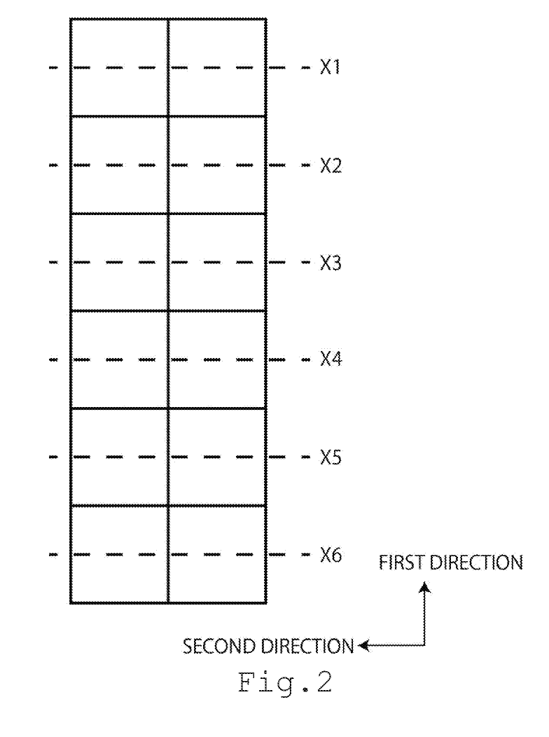

The content of Sb and F dopants can be evaluated by secondary ion mass spectrometry (SIMS). As shown in the image drawing of FIG. 2, the first electrode 4-facing surface of the light absorbing layer 3 is equally divided into 12 regions (2 crosswise×6 lengthwise) in a grid pattern, and the central portion of each region is subjected to SIMS analysis, from which the average dopant content is determined and evaluated. The surface is divided into 6 regions in the long side direction and into 2 regions in the short side direction. When the surface has a regular square shape, it may be divided into 6 regions in any direction. The region to be analyzed is a surface including the oxide layer 2. The content of Sb and F dopants can be determined from a calibration curve prepared using standard samples for the concentration of Sb and F in the oxide layer 2. The thickness of each layer and the thickness, gap (gap width), and height of the first electrode 4 may be determined by observing the cross-section of the solar cell 100 with a scanning electron microscope (SEM). The composition of each layer may be determined by observing the cross-section and performing elemental analysis using a scanning electron microscope equipped with an energy dispersive X-ray analyzer (scanning electron microscope energy dispersed X-ray spectrometry (SEM-EDX)).

The oxide layer 2 preferably includes a SnO₂ layer. A layer including an oxide such as InO₂, TiO₂, or ZnO may be present as a part of the oxide layer 2 or disposed on the oxide layer 2 between the substrate 1 and the SnO₂ layer of the oxide layer 2. A layer including InO₂ and one or both of SnO₂ and TiO₂ may be present as a part of the oxide layer 2 or disposed on the oxide layer 2 between the light absorbing layer 3 and the SnO₂ layer of the oxide layer 2. In the case where the oxide layer 2 has a laminated structure, the oxide layer 2 preferably includes InO₂ and SnO₂ stacked from the substrate 1 side to the light absorbing layer 3 side or preferably includes InO₂, SnO₂, and TiO₂ stacked on one another. The oxide layer 2 has a part in contact with the light absorbing layer 3. Such a part is preferably an oxide layer of at least one of InO₂, SnO₂, and TiO₂ because such an oxide layer resists lattice mismatch-induced delamination from the light absorbing layer 3 and has good adhesion.

In addition, a layer containing an oxide such as SiO₂ (insulating layer) may be further provided between the substrate 1 and the oxide layer 2. The oxide layer 2 containing a SiO₂ layer is preferred because the SiO₂ layer can function as a barrier layer for suppressing the diffusion of impurities from the substrate 1 into the oxide layer 2 and the light absorbing layer 3.

The oxide layer 2 and the SiO₂ layer can be formed by sputtering or other deposition methods onto the substrate 1.

The oxide layer 2 typically has a thickness of 10 nm to 1 μm. Too thin an oxide layer 2 is not preferred because it may fail to ensure sufficient coverage, so that the light absorbing layer 3 may be formed directly on the substrate 1 and thus more likely to peel off and may have poor adhesion. Too thick an oxide layer 2 is not preferred because it can inhibit the diffusion of alkali elements from the substrate 1. More preferably, the thickness of the oxide layer 2 is 10 nm to 500 nm. The high transparency of the solar cell of this embodiment is an advantageous characteristic for use as a top or middle cell of a multi-junction solar cell. In addition, the solar cell of this embodiment is advantageous for use in not only multi-junction solar cells but also in solar cell applications requiring transparency.

(First Electrode)

The first electrode 4 is a line-patterned or mesh-patterned electrode. The line-patterned electrode is composed of a single line-patterned conductive member or a plurality of line-patterned conductive members. The mesh-patterned electrode is composed of a single mesh-patterned conductive member or a plurality of mesh-patterned conductive members. The first electrode 4 in a line or mesh pattern is a light transmitting member because the pattern shape of the first electrode 4 is the line or mesh pattern. The first electrode 4, which is in direct contact with the light absorbing layer 3, functions as an electrode of the solar cell 100. A line-patterned electrode and a mesh-patterned electrode may be combined to form the first electrode 4.

In this embodiment, the line-patterned or mesh-patterned conductive member has a line or mesh pattern formed between the oxide layer 2 and the light absorbing layer 3. The first electrode 4 is not a solid film but has an aperture ratio of 50% or more. The aperture ratio indicates the ratio of the aperture of the first electrode to the high-resistance oxide layer, more specifically, the ratio of the area occupied by the conductive member(s) of the first electrode 4 to the area of the oxide layer 2 ([the area occupied by the conductive member(s) of the first electrode 4]/[the area of the oxide layer 2]).

The aperture ratio of the first electrode 4 is preferably 50% to 99%. If the aperture ratio is less than 50%, the optical transparency will decrease, which is not preferred. An aperture ratio of less than 98% should be written to two significant figures (rounded off). Also, if the aperture ratio exceeds 99%, the current collection rate of the solar cell 100 can decrease so that the amount of power generation by the solar cell 100 can decrease, which is not preferred. The aperture ratio is more preferably 65% to 99% or 80% to 99%.

The first electrode 4 with a high aperture ratio has high transparency. A certain contact resistance can be generated between the compound semiconductor and the high-resistance oxide layer (a certain contact resistance will be generated if carrier doping is performed even slightly). However, a good contact can be formed between them because the conduction through the low-resistance line is dominant at this portion and an oxide film is hardly formed at the portion where the line exists. Therefore, the current is collected at the line portion, and the first electrode 4 can function effectively while maintaining a high aperture ratio.

FIG. 3 is a schematic perspective view of the solar cell 100 having a line-patterned first electrode 4. The schematic perspective view shows line-patterned conductive members 4a of the first electrode 4. A plurality of line-patterned conductive members 4a are provided on the oxide layer 2. FIG. 3 also shows internal line-patterned conductive members 4a. W1 represents the width of the line-patterned conductive member, P1 the gap between the line-patterned conductive members 4a, and H1 the height of the line-patterned conductive member. The line-patterned conductive member 4a has an electrode structure extending in one direction. The first electrode 4 extends in an in-plane direction parallel to the first and second directions. The third direction perpendicular to the first and second directions is the direction in which the components for the solar cell 100 are stacked and is also the height direction of the first electrode 4.

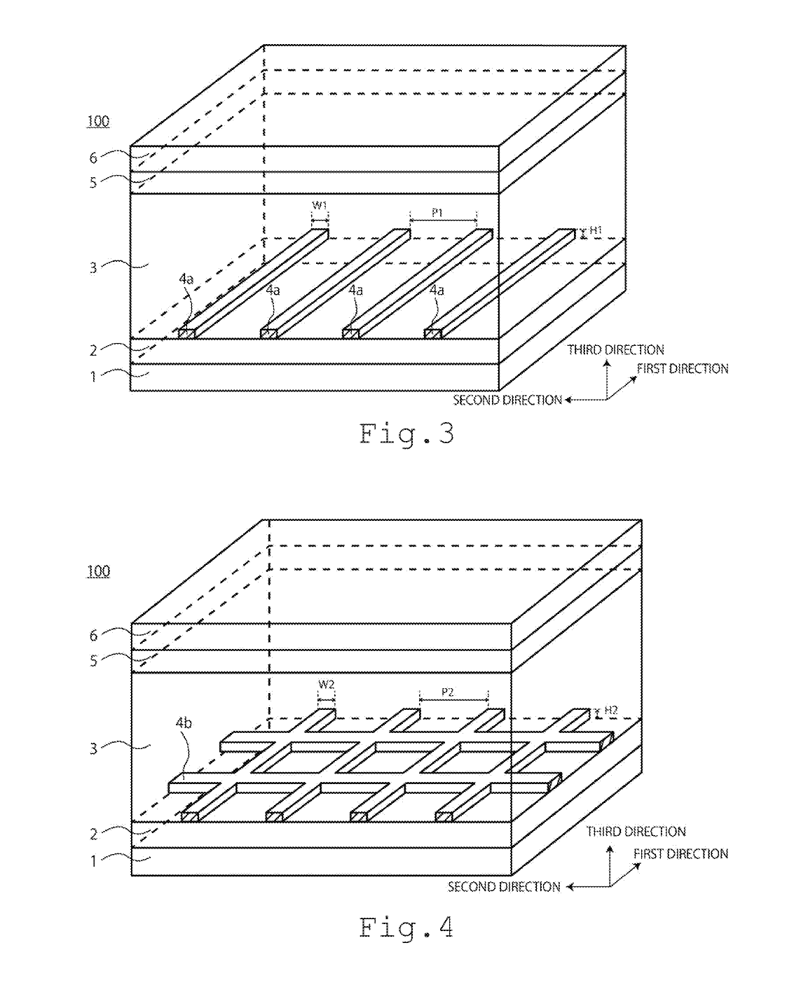

FIG. 4 is a schematic perspective view of the solar cell 100 of this embodiment having a mesh-patterned first electrode 4. The schematic perspective view shows a mesh-patterned conductive member 4b of the first electrode 4. The mesh-patterned conductive member 4b is provided on the oxide layer 2. FIG. 4 also shows an internal mesh-patterned conductive member 4b. W2 represents the width of the mesh-patterned conductive member 4b, P2 the gap of the mesh-patterned conductive member, and H2 the height of the mesh-patterned conductive member 4b. In the mesh-patterned conductive member 4b, line-patterned conductive parts extending in two directions intersect with each other to form a mesh-patterned electrode structure. The mesh-patterned conductive member 4b has an electrode structure in which line components extend in at least two directions and intersect with each other. In FIG. 4, the mesh-patterned conductive member 4b has an electrode structure in which line components extend in the first and second directions and cross each other at right angles. The first electrode 4 extends in in-plane directions parallel to the first and second directions. The third direction perpendicular to the first and second directions is the direction in which the components for the solar cell 100 are stacked and is also the height direction of the first electrode 4.

The first electrode 4 has a non-aperture portion in which the line-patterned conductive member 4a or the mesh-patterned conductive member 4b is provided. In the non-aperture portion, the line-patterned conductive member 4a or the mesh-patterned conductive member 4b is in direct contact with the oxide layer 2-facing surface of the light absorbing layer 3. The surface of the line-patterned conductive member 4a or the mesh-patterned conductive member 4b, opposite to its surface in contact with the light absorbing layer 3, is in contact with the light absorbing layer 3-facing surface of the oxide layer 2. The first electrode 4 has high transparency to the oxide layer 2 and has an effect of suppressing oxidation of the compound semiconductor in the light absorbing layer 3. In contrast to a transparent electrode having optical transparency, the first electrode 4 has the function of suppressing the formation of an oxidized region at the interface between the electrode and the compound semiconductor and can concentrate the electric field at the conductive member area, because the line-patterned conductive member 4a or the mesh-patterned conductive member 4b forms the contact area, and thus the first electrode 4 can suppress the recombination at the interface and improve the open circuit voltage. As the oxidation of the light absorbing layer 3 is suppressed, the open circuit voltage and the conversion efficiency are improved. The function of preventing the oxidation of the light absorbing layer 3 can be achieved even at a very high aperture ratio.

The line-patterned or mesh-patterned conductive member 4a or 4b of the first electrode 4 is preferably made of a material non-reactive or almost non-reactive with the light absorbing layer 3. Therefore, the conductive member of the first electrode 4 preferably includes at least one selected from the group consisting of: a metal, an alloy, and a conductive oxide. In a case where the light absorbing layer 3 contains Se and S, the conductive member of the first electrode 4 is preferably made of a material capable of withstanding corrosion by Se and S. The metal is preferably a noble metal element or Mo. Therefore, the metal or alloy in the conductive member of the first electrode 4 preferably includes at least one selected from the group consisting of: Mo, Ru, Rh, Pd, Ag, Ir, and Pt. In view of resistance to corrosion by Se and S, the conductive oxide is preferably at least one selected from the group consisting of: RuO₂, PdO, Rh₂O₃, PtO₂, and IrO₂. In addition, the metal is preferably capable of forming an ohmic contact with the light absorbing layer 3. Metals or compounds with a high work function (oxides and nitrides) are preferred. Metals or compounds (oxides) with a work function of 5.4 eV or more are preferred. From these points of view, the conductive member of the first electrode 4 more preferably includes at least one selected from the group consisting of: Mo, Pt, Ir, and Pd.

The line-patterned or mesh-patterned conductive member 4a or 4b may have any cross-sectional shape. Specific examples of the cross-sectional shape of the line-patterned or mesh-patterned conductive member 4a or 4b include a circular shape, an elliptical shape, a polygonal shape, an M shape, and a multi-line shape. The circular, elliptical, and polygonal shapes may be, but not limited to, hollow (such as O-shaped).

The width (W1) of the line-patterned conductive member 4a and the width (W2) of the mesh-patterned conductive member 4b are preferably 10 nm to 100 μm. The width (W1) of the line-patterned conductive member 4a and the width (W2) of the mesh-patterned conductive member 4b are more preferably 30 nm to 10 μm. The line-patterned conductive member 4a with too small a width W1 and the mesh-patterned conductive member 4b with too small a width W2 are difficult to form on the surface of the oxide layer 2. The line-patterned conductive member 4a with too large a width W1 and the mesh-patterned conductive member 4b with too large a width W2 can cause variations in optical transparency or make the light absorbing layer 3 vulnerable to oxidation and thus are not preferred.

The height H1 of the line-patterned conductive member 4a and the height H2 of the mesh-patterned conductive member 4b are preferably 10 nm to 50 μm in view of ease of manufacture. The line-patterned conductive member 4a with too large a height H1 and the mesh-patterned conductive member 4b with too large a height H2 are difficult to form and not preferred in view of optical transparency to obliquely incident light. In a case where the mobility of the light absorbing layer 3 is not so high, multiple lines or a mesh of multiple lines crossing each other is preferably used so that a high aperture ratio can be achieved while the gap (gap width/area) between the metal parts is reduced.

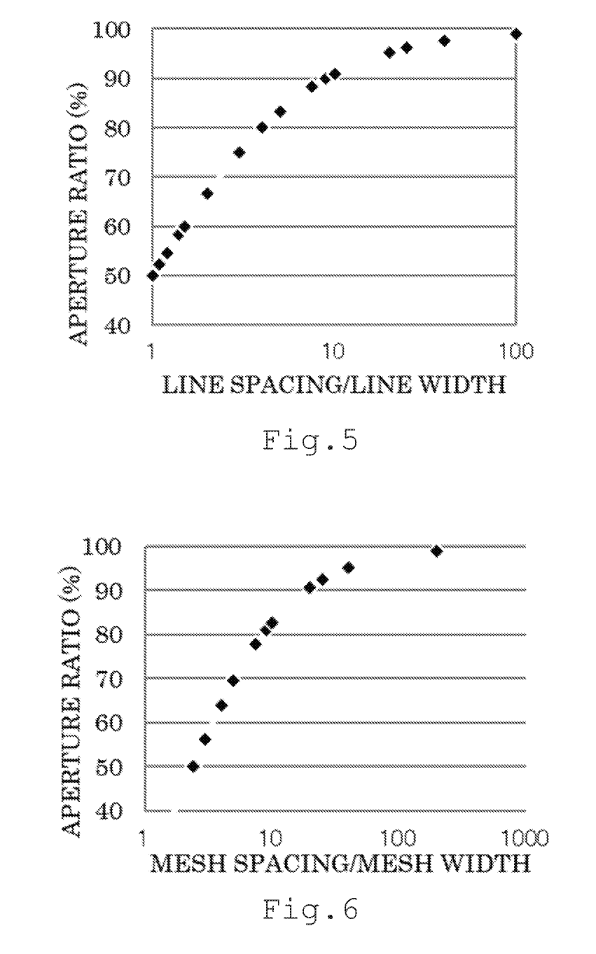

The gap P1 between the line-patterned conductive members 4a and the gap P2 of the mesh-patterned conductive members 4b are preferably 10 nm to 100 μm. The width W1 of the line-patterned conductive members 4a and the gap P1 between the line-patterned conductive members 4a can be controlled within the range where the relationship shown by the graph of FIG. 5 is satisfied between the line gap, the line width, and the aperture ratio (the relationship between (line gap P1)/(line width W1) and the aperture ratio). Specifically, in the case where the first electrode 4 is line-patterned, the aperture ratio can be calculated by the equation: the aperture ratio=(line gap P1)/(line gap P1+line width W1)×100. The above aperture ratio can be satisfied when the ratio (line gap P1)/(line width W1) is 1 to 99. The width W2 of the mesh-patterned conductive member 4b and the gap P2 of the mesh-patterned conductive member 4b can be controlled within the range where the relationship shown by the graph of FIG. 6 is satisfied between (mesh gap P2)/(mesh width W2) and the aperture ratio. In the case where the first electrode is mesh-patterned, the aperture ratio can be calculated by the equation: the aperture ratio=((mesh gap P2)/(mesh gap P2+mesh width W2))²×100. The above aperture ratio can be satisfied when the ratio (mesh gap P)/(mesh width W2) is 2.42 to 199.

It is preferable that the line-patterned conductive members 4a and the mesh-patterned conductive member 4b be uniformly arranged between the light absorbing layer 3 and the oxide layer 2. Therefore, it is preferable that the line-patterned conductive members 4a and the mesh-patterned conductive member 4b satisfy, as a whole, the above aperture ratio. The uniform arrangement of the line-patterned conductive members 4a and the mesh-patterned conductive member 4b can reduce variations in optical transparency and improve the optical characteristics of the solar cell 100. In addition, when lines with the same width are arranged with the same aperture ratio, more uniform arrangement can improve the function of preventing oxidation of the light absorbing layer 3 and thus is preferred. If the line-patterned conductive members 4a and the mesh-patterned conductive member 4b have large variations in height, large variations can occur in the transmission of light obliquely incident on the solar cell. Therefore, the difference between the average and maximum values of the line width W1 is preferably 10% or less, and the difference between the average and minimum values of the line width W1 is preferably 10% or less. In addition, the difference between the average and maximum values of the line gap P1 is preferably 10% or less, and the difference between the average and minimum values of the line gap P1 is preferably 10% or less. In addition, the difference between the average and maximum values of the line height H1 is preferably 10% or less, and the difference between the average and minimum values of the line height H1 is preferably 10% or less. In addition, the difference between the average and maximum values of the mesh width W2 is preferably 10% or less, and the difference between the average and minimum values of the mesh width W2 is preferably 10% or less. In addition, the difference between the average and maximum values of the mesh gap P2 is preferably 10% or less, and the difference between the average and minimum values of the mesh gap P2 is preferably 10% or less. In addition, the difference between the average and maximum values of the mesh height H2 is preferably 10% or less, and the difference between the average and minimum values of the mesh height H2 is preferably 10% or less.

When the mesh-patterned conductive member 4b is used to form the first electrode 4, the width, gap, and height of the mesh are parameters in each of the first and second directions, because the mesh-patterned conductive member 4b extends in the first and second directions. It is preferable that the width, gap (gap width), and height of the mesh, as parameters in each of the first and second directions, fall within the ranges mentioned above.

The line-patterned electrode has a structure in which line-patterned conductive members 4a extend in one direction. In the mesh-patterned electrode, however, line-patterned conductive parts extend in two directions to form the mesh. Therefore, the mesh-patterned electrode more frequently come into direct contact with the crystals in the light absorbing layer 3 than the line-patterned electrode. Therefore, the mesh-patterned electrode is more advantageous for the correction of photo-generated carriers. High transparency is an advantageous characteristic for use as a top cell on the light incident side of a multi-junction solar cell. In addition, the solar cell of this embodiment is advantageous for use in not only multi-junction solar cells but also in solar cell applications requiring transparency.

The line-patterned and mesh-patterned electrodes can be formed by a method including forming a metal film, an oxide film, or a nitride film and processing the film into a desired pattern using a mask or by a method including performing imprinting using a mold having a line or mesh pattern.

(Light Absorbing Layer)

In this embodiment, the light absorbing layer 3 is a p-type compound semiconductor layer. The light absorbing layer 3 is disposed between the oxide layer 2 and the n-type layer 5. The light absorbing layer 3 includes a compound containing Group I, Group III, and Group VI elements. The Group I element preferably includes at least Cu. The Group III element preferably includes at least Ga. The Group VI element preferably includes at least Se. The light absorbing layer may be a layer of a compound semiconductor including Group I (Ib), Group III (IIIb), and Group VI (VIb) elements and having a chalcopyrite structure, such as Cu(In,Ga)Se₂, CuInTe₂, CuGaSe₂, Cu(In,Al)Se₂, Cu(Al,Ga)(S,Se)₂, Cu(In,Ga)(S,Se)₂, CuGa(S,Se)₂, or Ag(In,Ga)Se₂. The Group Ib element or elements preferably include Cu or Cu and Ag. The Group IIIb element or elements preferably include one or more elements from the group consisting of: Ga, Al, and In. The Group VIb element or elements preferably include one or more elements from the group consisting of: Se, S, and Te. In particular, the Group Ib element more preferably includes Cu, the Group IIIb element or elements more preferably include Ga or Al or Ga and Al, and the Group VIb element or elements more preferably include Se or S or Se and S. When the content of In as a Group IIIb element is low, the band gap of the light absorbing layer 3 can be easily adjusted to a suitable value for the top cell of a multi-junction solar cell, which is preferred. The light absorbing layer 3 typically has a thickness of 800 nm to 3,000 nm. The magnitude of the band gap can be easily controlled to the desired value by using a combination of elements. The desired band gap value is, for example, 1.0 eV to 2.7 eV. The method for forming the light absorbing layer 3 may be any method, such as a three-stage vapor deposition process, capable of forming the light absorbing layer 3 on the oxide layer 2 provided with the first electrode 4. The solar cell may have an intermediate layer on the oxide layer 2, in which the first electrode 4 may be formed on the intermediate layer. Even in such a case, the same method may be used to form the light absorbing layer 3.

(n-Type Layer)

In this embodiment, the n-type layer 5 is an n-type semiconductor layer. The n-type layer 5 is disposed between the light absorbing layer 3 and the second electrode 6. The n-type layer 5 is in direct contact with the surface of the light absorbing layer 3 opposite to its surface facing the oxide layer 2. In addition, the n-type layer 5 forms a hetero-junction with the light absorbing layer 3. The n-type layer 5 is preferably an n-type semiconductor whose Fermi level is so controlled that the resulting photoelectric conversion device can have a high open-circuit voltage. The n-type layer 5 may include, for example, Zn_{1-y}M_{y}O₁₋ₓSₓ, Zn_{1-y-z}Mg_{z}M_{y}O, ZnO₁₋ₓSₓ, Zn_{1-z}Mg_{z}O (M is at least one element selected from the group consisting of: B, Al, In, and Ga, 0≤x≤1, 0<y<1, 0<z<1), CdS, or n-type GaP with a controlled carrier concentration. The n-type layer 5 preferably has a thickness of 2 nm to 800 nm. The n-type layer 5 may be deposited by, for example, sputtering or chemical bath deposition (CBD). In a case where CBD is performed, the n-type layer 5 can be formed on the light absorbing layer 3, for example, by chemical reaction of a metal salt (e.g., CdSO₄) and a sulfide (thiourea) with a complexing agent (ammonia) in an aqueous solution. The n-type layer 5 preferably includes CdS in a case where the light absorbing layer 3 includes a chalcopyrite compound free of In as a Group IIIb element, such as CuGaSe₂, AgGaSe₂, CuGaAlSe₂, or CuGa (Se, S)₂.

(Thin Oxide Layer) In this embodiment, a thin oxide layer is preferably disposed between the n-type layer 5 and the second electrode 6. The thin oxide layer may be a thin film including at least one compound selected from Zn₁₋ₓMgₓO, ZnO_{1-y}S_{y}, and Zn₁₋ₓMgₓO_{1-y}S_{y} (0≤x≤1, 0≤y<1). The thin oxide layer may fail to completely cover the entire surface of the n-type layer 5 facing the second electrode 6. For example, the thin oxide layer may cover 50% of the surface of the n-type layer 5 on the second electrode 6 side. Other candidates for the thin oxide layer include wurtzite-type AlN, GaN, and BeO. The thin oxide layer with a volume resistivity of 1 Ωcm or more is advantageous in that it can suppress a leakage current, which would otherwise be derived from a low-resistance component potentially existing in the light absorbing layer 3. In this embodiment, the thin oxide layer may be omitted. The thin oxide layer is preferably an oxide particle layer having a large number of voids therein. The intermediate layer is not limited to the compounds and physical properties mentioned above, and may be any layer capable of contributing to an improvement in the conversion efficiency of the solar cell and other purposes. The intermediate layer may include a plurality of layers with different physical properties.

(Second Electrode)

In this embodiment, the second electrode 6 is an electrode film electrically conductive and transparent to light such as sunlight. The second electrode 6 is in direct contact with the surface of the intermediate layer or the n-type layer 5 opposite to its surface facing the light absorbing layer 3. The light absorbing layer 3 and the n-type layer 5 joined to each other are disposed between the second electrode 6 and the oxide layer 2. The second electrode 6 is deposited by, for example, sputtering in an Ar atmosphere. For example, the second electrode 6 may include ZnO:Al produced with a ZnO target containing 2 wt % of alumina (Al₂O₃) or include ZnO:B containing B as a dopant derived from diborane or triethylboron.

(Third Electrode)

In this embodiment, a third electrode may be provided for the solar cell 100. The third electrode is a metal film formed on the surface of the second electrode opposite to its surface on the light absorbing layer 3 side. The third electrode may be a film of a conductive metal such as Ni or Al. The third electrode typically has a thickness of 200 nm to 2,000 nm. The third electrode may be omitted, for example, when the second electrode 6 has a low resistance so that the series resistance component is negligible.

(Anti-Reflection Film)

In this embodiment, an anti-reflection film may be provided to facilitate the introduction of light into the light absorbing layer 3. Such an anti-reflection film is formed on the surface of the second electrode 6 or the third electrode opposite to its surface on the light absorbing layer 3 side. The anti-reflection film is preferably made of, for example, MgF₂ or SiO₂. In this embodiment, the anti-reflection film may be omitted. The anti-reflection film is preferably vapor-deposited with a thickness of 70 to 130 nm (80 to 120 nm) though the thickness needs to be controlled according to the refractive index of each layer.

### Second Embodiment

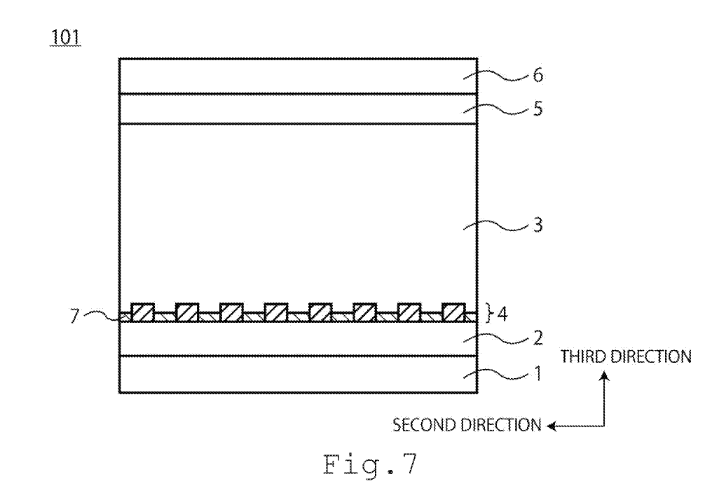

As shown in the schematic cross-sectional view of FIG. 7, a solar cell 101 according to this embodiment includes a substrate 1 and an oxide layer 2 on the substrate 1. A light absorbing layer 3 and an n-type layer 5 are disposed between the oxide layer 2 and a second electrode 6. In addition, the light absorbing layer 3 is disposed between the oxide layer 2 and the n-type layer 5. A first electrode 4 is disposed between the oxide layer 2 and the light absorbing layer 3. A first insulating film 7 is disposed between the conductive parts of the first electrode 4. The features other than the first insulating film 7 are similar to those of the solar cell 100 of the first embodiment. The description of the similar features of the second embodiment to those of the first embodiment will be omitted here.

(First Insulating Film)

In the area between the light absorbing layer 3 and the oxide layer 2, the first insulating film 7 is disposed between gaps of the line-patterned conductive members 4a of the first electrode 4 or between gaps of the mesh-patterned conductive member 4b of the first electrode 4. In other words, the first insulating film 7 is disposed on the whole or part of the surface of the oxide layer 2 not covered with the conductive member or members of the first electrode 4 between the light absorbing layer 3 and the oxide layer 2. The first insulating film 7 is an optically transparent film capable of preventing oxidation of the light absorbing layer 3. The light absorbing layer 3-facing surface of the oxide layer 2 is in direct contact with the oxide layer 2-facing surface of the first insulating film 7. The oxide layer 2-facing surface of the light absorbing layer 3 is in physical contact with the light absorbing layer 3-facing surface of the first insulating film 7. The side surface of the first insulating film 7, in other words, the surface facing the conductive member of the first electrode 4 is in direct contact with the conductive member of the first electrode 4 or the light absorbing layer 3. The line-patterned conductive members 4a or the mesh-patterned conductive member 4b can partially prevent the oxidation of the light absorbing layer 3. In order to prevent the oxidation, it is preferable to reduce the aperture ratio of the line-patterned conductive members 4a or the mesh-patterned conductive member 4b. However, such a reduction will lead to a reduction in the light transmittance, which is not preferred.

The first insulating film 7 may include an oxide or non-oxide material less likely to abstract oxygen than the oxide layer 2. In this case, oxidation can be suppressed at the interface between the oxide layer 2 and the light absorbing layer 3 so that the fill factor FF and the conversion efficiency can be improved. The oxide or non-oxide material for the first insulating film 7 is a non-doped (0 at %) material. In this regard, the oxide of the first insulating film 7 may be quantitatively analyzed by EDX. If the result is not more than the detection limit (for example), the oxide or non-oxide material can be determined to be non-doped. The first insulating film 7 may be either an oxide film or a nitride film.

Specifically, the oxide film is preferably a film of one or more selected from AlOₓ, MgO, and (Al, Mg) Oₓ. The nitride film is preferably a film of one or more selected from SiNₓ, AlNₓ, GaNₓ, and (Si, Al, Ga)Nₓ. The thickness of the first insulating film 7 may be greater than the height of the line or the line of the mesh region. Preferably, the thickness of the first insulating film 7 is not more than the height of the line-patterned conductive member 4a or the mesh-patterned conductive member 4b and 1 nm to 200 nm. More preferably, the thickness of the first insulating film 7 is not more than the height of the line-patterned conductive member 4a or the mesh-patterned conductive member 4b and 5 nm to 100 nm. The first insulating film 7 can have the advantageous effect described above even if it does not completely cover the entire surface between the lines in the area between the light absorbing layer 3 and the oxide layer 2. In view of prevention of oxidation, improvement of FF, and film formation process, the first insulating film 7 is preferably disposed over the entire area between the light absorbing layer 3 and the oxide layer 2.

In the case where the first insulating film 7 is a nitride, a layer including an oxide (insulating film) such as Ta₂O₅, CeO₂, or ZrO may be further disposed between the oxide layer 2 and the first insulating film 7. When the first insulating film 7 includes a Ta₂O₅ layer, higher adhesion can be obtained between the oxide layer 2 and the first insulating film 7, which is preferred.

The first insulating film 7 can be formed using a semiconductor manufacturing process. For example, a metal film, which is to be processed into line-patterned conductive members 4a or a mesh-patterned conductive member, is formed on the oxide layer 2 and then patterned into lines or a mesh using a resist mask, so that line-patterned conductive members 4a or a mesh-patterned conductive member (first electrode 4) is formed. Subsequently, a material for forming the first insulating film 7 is deposited on the exposed surface of the oxide layer 2 and on the resist mask for the line-patterned conductive members 4a or the mesh-patterned conductive member 4b by chemical vapor deposition (CVD), sputtering, or other techniques. The resist mask and the material for the first insulating film 7 on the line-patterned conductive members 4a or the mesh-patterned conductive member 4b are removed, which may be followed by the formation of the light absorbing layer 3 as in the first embodiment.

The oxide layer 2 acts to make the light absorbing layer 3 and the first electrode 4 resistant to delamination from the substrate 1 (to improve their adhesion). However, the oxide layer 2 forms an oxide layer at the interface with the light absorbing layer 3, so that recombination cannot be prevented at the interface. In this regard, the first insulating film acts to prevent oxidation of the light absorbing layer 3. When an oxide or nitride less likely to abstract oxygen than the oxide layer 2 is used to form the first insulating film on the oxide layer 2, oxidation can be suppressed at the interface of the light absorbing layer, so that recombination at the interface can be suppressed and the fill factor FF can be improved. In addition, the first insulating film 7 can completely suppress the injection of carriers into portions other than the first electrode 4, which makes it possible to maintain a high open-circuit voltage.

### Third Embodiment

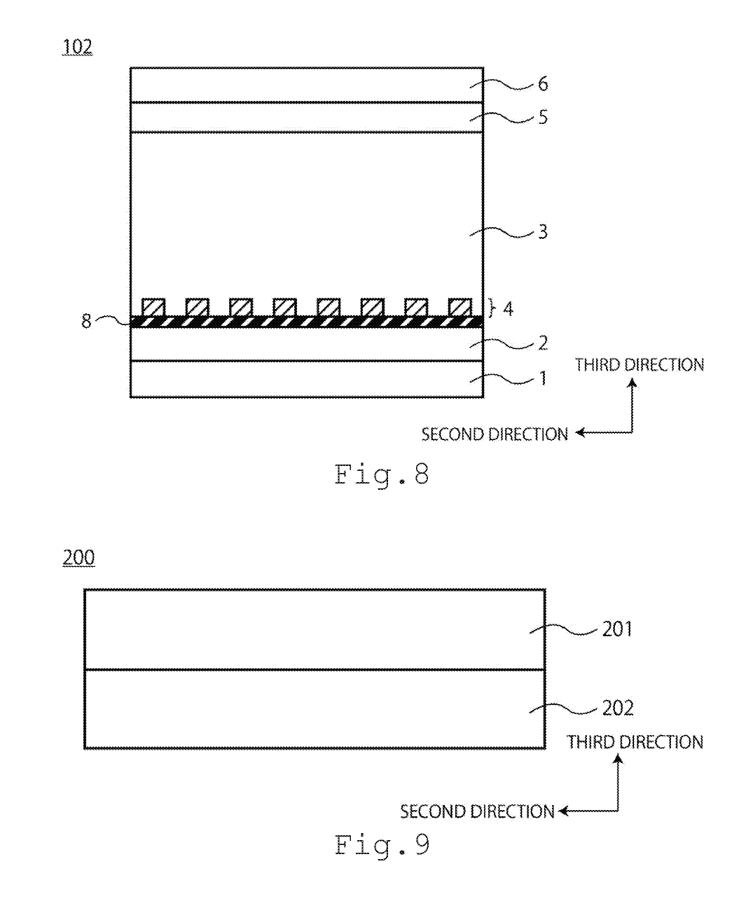

As shown in the schematic cross-sectional view of FIG. 8, a solar cell 102 according to this embodiment includes a substrate 1 and an oxide layer 2 on the substrate 1. A light absorbing layer 3 and an n-type layer 5 are disposed between the oxide layer 2 and a second electrode 6. In addition, the light absorbing layer 3 is disposed between the oxide layer 2 and the n-type layer 5. A first electrode 4 is disposed between the oxide layer 2 and the light absorbing layer 3. A second insulating film 8 is disposed between the first electrode 4 and the oxide layer 2. The features other than the second insulating film 8 are similar to those of the solar cell 100 of the first embodiment. The description of the similar features of the third embodiment to those of the first embodiment will be omitted here. Note that the first insulating film 7 according to the second embodiment may be used in combination with the second insulating film 8 according to this embodiment.

(Second Insulating Film)

The second insulating film 8 is disposed between the oxide layer 2-facing surface of the light absorbing layer 3 and the light absorbing layer 3-facing surface of the oxide layer 2 and between the oxide layer 2-facing surface of the first electrode 4 and the first electrode 4-facing surface of the oxide layer 2. The second insulating film 8 may include an oxide or non-oxide material less likely to abstract oxygen than the oxide layer 2. In this case, oxidation can be suppressed at the interface between the oxide layer 2 and the light absorbing layer 3 so that the fill factor FF and the conversion efficiency can be improved. The second insulating film 8 is formed by, for example, chemical vapor deposition (CVD) or sputtering. The thickness of the second insulating film 8 is preferably 1 nm to 200 nm. The second insulating film 8 may also be a stack of different materials. In order to make the manufacture easier in the third embodiment using the second insulating film 8 than in the second embodiment, the first insulating film 7 may be formed on the oxide layer 2 without being embedded between the line-patterned conductive members 4a or into the openings of the mesh-patterned conductive member (first electrode 4), and the line-patterned conductive members 4a or the mesh-patterned conductive member 4b (first electrode 4) may be formed on the first insulating film 7.

### (Fourth Embodiment) (Multi-Junction Solar Cell)

A fourth embodiment is directed to a multi-junction solar cell including the solar cell of the first embodiment. FIG. 9 is a schematic cross-sectional view showing a multi-junction solar cell according to the fourth embodiment. The multi-junction solar cell of FIG. 9 includes a top solar cell 201 and a bottom solar cell 202. The solar cells 100, 101, and 102 of the first, second, and third embodiments may each be used as the top cell 201 for the multi-junction solar cell 200. The bottom cell 202 may be, for example, a solar cell having a light absorbing layer of Si or any one of the solar cells 100, 101, and 102 of the first, second, and third embodiments having the light absorbing layer 3 with a gap narrower than that in the top solar cell 201. In the case where the solar cell 100 of the first embodiment is used as the top cell, the Group I, III, and VI elements are preferably Cu, Ga, and Se, respectively, in view of absorption wavelength and conversion efficiency. The solar cell of the first embodiment, in which the light absorbing layer has a wide gap, is preferably used as the top cell. In the case where the solar cell 100 of the first embodiment is used as the bottom cell, the Group I element is preferably Cu, the group III elements are preferably In and Ga, and the group VI element is preferably Se, in view of absorption wavelength and conversion efficiency.

### (Fifth Embodiment) (Solar Cell Module)

A fifth embodiment is directed to a solar cell module in which the solar cells of the first to fourth embodiments may each be used as a power generating element. The power generated by the solar cell of the embodiment is consumed by a load electrically connected to the solar cell or stored in a storage battery electrically connected to the solar cell.

The solar cell module according to this embodiment may have a structure including a support member such as a glass; and a single solar cell fixed on the support member or a component including a plurality of solar cells connected in series or parallel or in series and parallel and fixed on the support member. The solar cell module may also have a light collector so that it can have a light-receiving area larger than the area of the solar cells for the conversion of light to electricity. The solar cells include solar cells connected in series, in parallel, or in series and parallel.

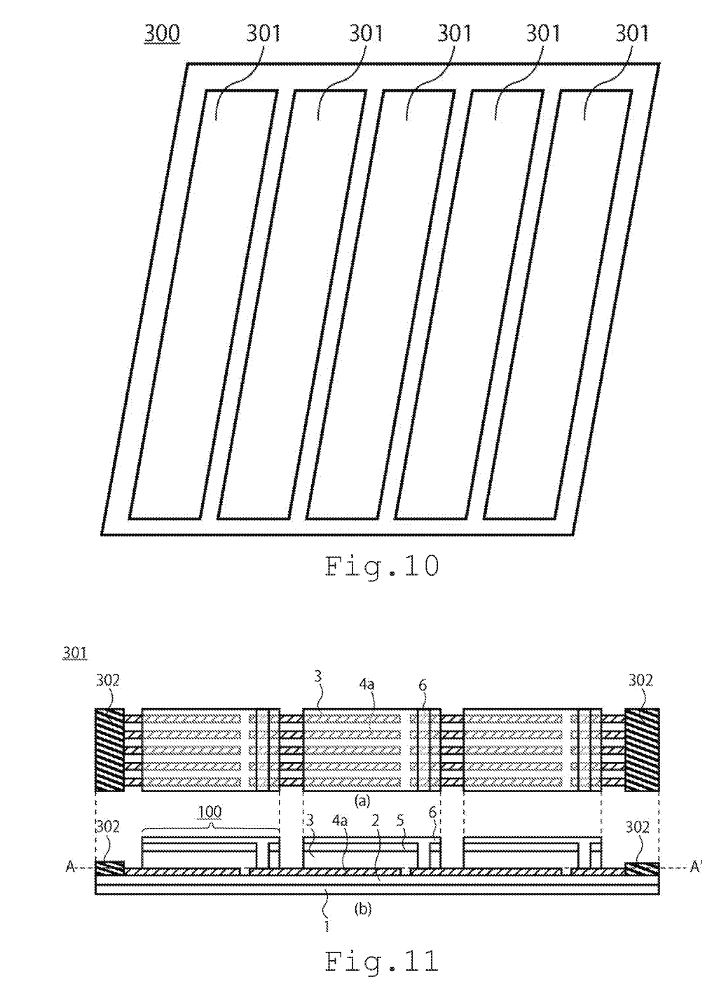

FIG. 10 is a schematic diagram showing a solar cell module 300 including five submodules 301 arranged in the crosswise direction, in which each submodule has a plurality of solar cells connected in series. In the solar cell module 300 of FIG. 10, the plurality of submodules 301 are preferably connected in series, in parallel, or in series and parallel as mentioned above, though the connection wiring is not shown. In each submodule 301, each solar cell is preferably the solar cell 100 of the first embodiment or the multi-junction solar cell 200 of the fourth embodiment. The solar cell module 300 of this embodiment may also have a module structure in which a module including the solar cells 100, 101, or 102 of the first, second, or third embodiment or the multi-junction solar cells 200 of the fourth embodiment is stacked on a module including other solar cells. It is also preferable to use any other structure capable of enhancing the conversion efficiency. In the solar cell module 300 of this embodiment, the solar cells are preferably provided on the light receiving surface side because they have a photoelectric conversion layer with a wide band gap.

FIGS. 11(a) and 11(b) are schematic plan and cross-sectional views showing the submodule 301 in which three solar cells each having line-patterned conductive members 4a of the first electrode according to the embodiment are connected in series. FIGS. 11(a) and 11(b) are partial drawings of the submodule. FIG. 11(a) is a plan view along the virtual plane A-A′ in FIG. 11(b). The submodule includes three solar cells (solar cells 100) electrically connected in series, in which bus bars 302 are connected at both ends to the line-patterned conductive members 4a, and the electricity generated by the solar cells 100 is taken from the bus bars 302. The line-patterned conductive members 4a, which form the first electrode 4 and extend in the lengthwise direction in the drawing, function as the lower electrodes of the solar cells 100 arranged in the lengthwise direction. Each second electrode 6 as an upper electrode extends through the light absorbing layer 3 and connects to the line-patterned conductive members 4a to form a series connection. Therefore, the line-patterned conductive member 4a is partially divided. A plurality of rows each including a plurality of line-patterned conductive members 4a are provided according to the number of the submodules, in which the line-patterned conductive members 4a function as an electrode of each solar cell while maintaining a certain aperture ratio.

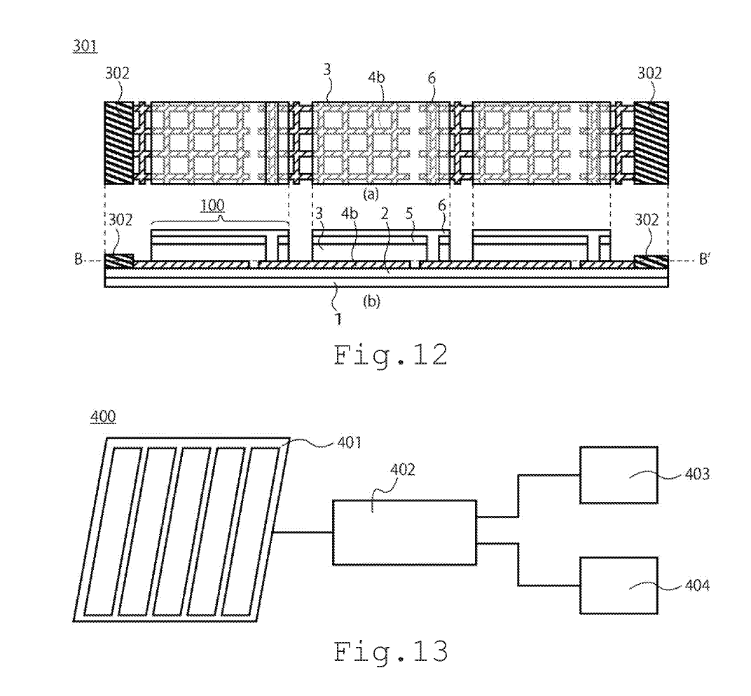

FIGS. 12(a) and 12(b) are schematic plan and cross-sectional views showing the submodule 301 in which three solar cells each having a mesh-patterned conductive member 4b of the first electrode according to the embodiment are connected in series. FIGS. 12(a) and 12(b) are partial drawings of the submodule. FIG. 12(a) is a plan view along the virtual plane B-B′ in FIG. 12(b). The submodule includes three solar cells (solar cells 100) electrically connected in series, in which bus bars 302 are connected at both ends to the mesh-patterned conductive members 4b, and the electricity generated by the solar cells 100 is taken from the bus bars 302. The mesh-patterned conductive members 4b, which each form the first electrode 4 and extend in the lengthwise and crosswise directions in the drawing, function as the lower electrodes of the solar cells 100 arranged in the lengthwise direction. Each second electrode 6 as an upper electrode extends through the light absorbing layer 3 and connects to the mesh-patterned conductive member 4b to form a series connection. Therefore, the mesh-patterned conductive member 4b is partially divided. A plurality of mesh-patterned conductive members 4b are provided according to the number of the submodules, in which each mesh-patterned conductive member 4b functions as an electrode of each solar cell while maintaining a certain aperture ratio. The schematic diagrams of FIGS. 11(a), 11(b), 12(a), and 12(b) show examples of the structure including the submodules 301 and the bus bars 302.

### Sixth Embodiment

The solar cell module 300 of the embodiment can be used as a power generator for generating electricity in a solar power generation system according to a sixth embodiment. The solar power generation system according to this embodiment is designed to generate electricity using the solar cell module. Specifically, the solar power generation system includes the solar cell module for generating electricity, a power converter for converting the generated electricity, and a storage unit for storing the generated electricity or a load for consuming the generated electricity. FIG. 13 is a schematic diagram showing the solar power generation system 400 according to this embodiment. The solar power generation system of FIG. 13 includes the solar cell module 401 (300), a converter 402, a storage battery 403, and a load 404. Any one of the storage battery 403 and the load 404 may be omitted. The load 404 may also be configured to be able to utilize the electric energy stored in the storage battery 403. The converter 402 is a device including a circuit or element, such as a DC-DC converter, a DC-AC converter, or an AC-AC converter, configured to perform power conversion such as transformation or DC-AC conversion. The converter 402 may have any suitable configuration depending on the generated voltage or the configuration of the storage battery 403 or the load 404.

The solar cells in the submodules 301 of the solar cell module 300 generate electricity when receiving light, and the electric energy is converted by the converter 402 and stored in the storage battery 403 or consumed by the load 404. The solar cell module 401 is preferably provided with, for example, a sunlight tracking drive unit for constantly directing the solar cell module 401 to the sun, a collector for collecting sunlight, or a device for improving power generation efficiency.

The solar power generation system 400 is preferably used for immovable objects such as houses, commercial facilities, and factories and for movable objects such as vehicles, aircraft, and electronic devices. It can be expected that the solar cell module 401 having the photoelectric conversion devices of the embodiment with a high conversion efficiency will produce a larger amount of electric power.

Hereinafter, embodiments will be described more specifically with reference to examples, which, however, are not intended to limit the embodiments.

### Example 1

Two solar cells: a top cell and a bottom cell are joined to form a multi-junction solar cell. Evaluations are made of the conversion efficiency of the multi-junction solar cell, the open circuit voltage (Voc) of the top cell, the short circuit current density (Jsc) of the top cell, the fill factor (FF) of the top cell, the light transmittance (average at wavelengths of 700 nm to 1,150 nm) of the top cell, the aperture ratio and conversion efficiency of the top cell, and the conversion efficiency of the bottom cell. First, a method for producing the top cell will be described. Soda-lime glass is used as a substrate. A 200-nm-thick oxide layer is formed by sputtering of non-carrier-doped, high-resistance SnO₂ (carrier concentration: 0.0%). Subsequently, a 100-nm-thick Mo film is formed on the oxide layer and then patterned using a mask to form a first electrode composed of line-patterned conductive members with a line width of 10 μm and a gap of 20 μm between lines. After organic washing, the substrate is heated to 370° C., and Ga and Se are vapor-deposited thereon. Cu and Se are then vapor-deposited thereon while the substrate is heated to a temperature of 550° C. When an endothermic reaction is observed, the deposition is continued for up to 10% of the Cu and Se deposition time, and finally, Ga and Se are vapor-deposited thereon. When the desired Cu/Ga composition is reached, the vapor deposition of Ga is stopped, and then the substrate temperature is lowered. When the substrate temperature drops to 380° C., the vapor deposition of Se is stopped.

Next, a CdS layer is formed as an n-type layer by chemical bath deposition (CBD). Cadmium sulfate is dissolved in an aqueous ammonia solution, to which thiourea is added. The substrate is immersed in the solution for 300 seconds and then taken out and washed with water. An organic Zn compound is applied to the substrate by spin coating. The coating is heated at 120° C. for 5 minutes to form a 30-nm-thick ZnO protective layer.

A second electrode (upper transparent electrode) is formed by sputtering of ZnO:Al. The substrate temperature is preferably 60 to 150° C. Relatively low temperature deposition can increase the open circuit voltage and thus is preferred.

Ni/Al is vapor-deposited as a third electrode (upper electrode). Ni is preferably first vapor-deposited so that conductivity can be maintained even if oxidation occurs at the interface with the transparent electrode. Al is then vapor-deposited thereon. The thicknesses of Ni and Al are preferably about 60 nm and about 500 nm, respectively.

A 100-nm-thick anti-reflection film is formed by vapor-deposition of MgF₂.

Next, a method for producing the bottom cell will be described. A 0.5-μm-thick Si wafer is provided, and its light-receiving side is doped with an n-type dopant by ion implantation. It is of n⁺ type because it can form good contact immediately below Ag wiring. An anti-reflection film is formed thereon. SiNₓ is used to form a passivation layer (region) on the back side. An SiNₓ-free part is formed, and an Al back electrode is connected to only part of the substrate, so that a high-efficiency bottom cell is obtained with reduced recombination at the crystal interface.

A method for measuring the conversion efficiency will be described. A solar simulator is used having a light source designed to simulate AM 1.5 G illumination. Under the light source, the intensity of light is adjusted to 1 sun using a reference Si cell. The temperature is 25° C. The current density (the value obtained by dividing the current by the cell area) is determined under voltage sweeping. In the graph with the horizontal axis representing voltage and the vertical axis representing current density, the intersection with the horizontal axis indicates the open circuit voltage Voc while the intersection with the vertical axis indicates the short circuit current Jsc. The fill factor and the efficiency are calculated by FF=(Vmpp*Jmpp)/(Voc*Jsc) and Efficiency Eff.=Voc*Jsc, respectively, where Vmpp and Jmpp are the voltage and the current density at the point where the product of the voltage and the current density reaches the maximum (maximum power point).

Using a spectrophotometer, the transmittance is measured as the ratio of the transmitted light to the incident light on the sample surface perpendicular to the light source. The reflectance is determined by measuring the reflected light from the sample inclined by about 5° to the vertically incident light. The band gap is determined from the transmittance and the reflectance. In Example 1, the average transmittance at wavelengths of 700 to 1,150 nm is calculated as an index in the range from the wavelength region where the transmission becomes high (e.g., a transmittance of at least 50%) at not more than the band gap to the wavelength absorbable by the bottom cell.

The results are summarized in Table 1. The results of other examples and comparative examples are also summarized in Table 1.

### Comparative Example 1

In Comparative Example 1, the top solar cell is produced by a method similar to that in Example 1, except that the first electrode and the high-resistance oxide layer are not formed and ITO (150 nm) and ATO (100 nm) (with carrier concentrations of 11.8% and 3.4%, respectively) are deposited on the soda-lime glass by sputtering to form an alternative first electrode. Using the top solar cell, a multi-junction solar cell of Comparative Example 1 is obtained by a method similar to that in Example 1. The solar cell is then evaluated by a method similar to that in Example 1.

The top cell has a high aperture ratio for the bottom cell. However, the top cell has a reduced Voc and a reduced FF due to oxidation at the interface between the ATO of the first electrode and the compound semiconductor by the high-temperature deposition.

### Examples 2 to 4

In each of Examples 2 to 4, the top solar cell is produced by a method similar to that in Example 1, except that the 100-nm-thick Mo film formed on the oxide layer is patterned using a mask to form a first electrode composed of line-patterned conductive members with a width of 4.5 μm and a gap of 10 μm between lines (Example 2), a first electrode composed of line-patterned conductive members with a width of 2 μm and a gap of 8 μm between lines (Example 3), or a first electrode composed of line-patterned conductive members with a width of 1 μm and a gap of 7 μm between lines (Example 4). Using the top solar cells, multi-junction solar cells of Examples 2 to 4 are obtained, respectively, by a method similar to that in Example 1. The solar cells are then evaluated by a method similar to that in Example 1.

The solar cells have efficiency higher than that of Example 1 due to differences in the aperture ratio and the current collection rate.

### Comparative Example 2

In Comparative Example 2, the top solar cell is produced by a method similar to that in Example 2, except that the oxide layer is not formed; ATO (200 nm) (carrier concentration 3.4%) is deposited on the soda-lime glass by sputtering to form a transparent electrode; a 100-nm-thick Mo film is then formed on the transparent electrode; and the Mo film is patterned using a mask to form a first electrode composed of line-patterned conductive members with a width of 4.5 μm and a gap of 10 μm between lines. Using the top solar cell, a multi-junction solar cell of Comparative Example 2 is obtained by a method similar to that in Example 2. The solar cell is then evaluated by a method similar to that in Example 2.

The use of carrier-doped ATO results in a reduction in infrared transmittance, and the transmission of light to the bottom cell is lower in Comparative Example 2 than in Example 2. In Comparative Example 2, a contact between the transparent electrode and the compound semiconductor is formed in addition to the contact between the metal and the compound semiconductor. Therefore, carriers are injected through the oxide layer formed at the contact interface with the transparent electrode, which leads to a reduction in the FF and Voc of the top cell and makes the efficiency of the top and bottom cells lower than that in Example 2.

### Example 5

In Example 5, a 100-nm-thick oxide layer is formed by sputtering of non-carrier-doped, high-resistance SnO₂ (carrier concentration: 0.0%). Subsequently, a 100-nm-thick Mo film is formed on the oxide layer and then patterned using a mask to form a first electrode composed of line-patterned conductive members with a line width of 4.5 μm and a gap of 10 μm between lines. Except for these points, the top cell is produced by a method similar to that in Example 1, and using the top cell, a multi-junction solar cell of Example 5 is obtained by a method similar to that in Example 1. The solar cell is then evaluated by a method similar to that in Example 1.

### Examples 6 and 7

In each of Examples 6 and 7, the top solar cell is produced by a method similar to that in Example 1, except that the 100-nm-thick Mo film formed on the oxide layer is patterned using a mask to form a first electrode composed of a mesh-patterned conductive member with a width of 2 μm and a gap of 10 μm (Example 6) or a first electrode composed of a mesh-patterned conductive member with a width of 1 μm and a gap of 10 μm (Example 7). Using the top solar cells, multi-junction solar cells of Examples 6 and 7 are obtained, respectively, by a method similar to that in Example 1. The solar cell is then evaluated by a method similar to that in Example 1.

The use of a mesh pattern successfully makes the gap between metal parts smaller than that obtained using a line pattern and also makes it possible to increase the current collection rate (current contribution rate) while maintaining a certain aperture ratio. In addition, the mesh electrode is less likely to break at some midpoint even when having a small line width.

### Example 8

In Example 8, lines are formed by imprinting, instead of forming a line pattern using a mask. The first electrode formed is composed of line-patterned conductive members with a line width of 250 nm and a gap of 2 μm between lines. The Mo thickness is 50 nm. Except for these points, the top solar cell is produced by a method similar to that in Example 1, and using the top cell, a multi-junction solar cell of Example 8 is obtained by a method similar to that in Example 1. The solar cell is then evaluated by a method similar to that in Example 1.

### Example 9

In Example 9, a 100-nm-thick Mo film is formed on the oxide layer and then patterned using a mask to form a first electrode composed of line-patterned conductive members with a line width of 2 μm and a gap of 8 μm between lines. Subsequently, SiNₓ is deposited with a thickness of 40 nm to form the first insulating layer. Except for these points, the top solar cell is produced by a method similar to that in Example 1, and using the top cell, a multi-junction solar cell of Example 9 is obtained by a method similar to that in Example 1. The solar cell is then evaluated by a method similar to that in Example 1.

The solar cell of Example 9 has a FF higher than that of Example 1 because the oxidation at the interface between the compound semiconductor and SnO₂ is further prevented.

### Example 10

In Example 10, a 200-nm-thick oxide layer is formed on the soda-lime glass by sputtering of ZnO. Subsequently, a 100-nm-thick Mo film is formed on the oxide layer and then patterned using a mask to form a first electrode composed of line-patterned conductive members with a line width of 4.5 μm and a gap of 10 μm between lines. Except for these points, the top cell is produced by a method similar to that in Example 1, and using the top cell, a multi-junction solar cell of Example 10 is obtained by a method similar to that in Example 1. The solar cell is then evaluated by a method similar to that in Example 1.

### Example 11

In Example 11, Pt is used instead of Mo to form a first electrode composed of line-patterned conductive members. The Pt thickness is 100 nm, the line width is 4.5 μm, and the gap between lines is 10 μm. Except for these points, the top solar cell is produced by a method similar to that in Example 1, and using the top solar cell, a multi-junction solar cell of Example 11 is obtained by a method similar to that in Example 1. The solar cell is then evaluated by a method similar to that in Example 1.

### Comparative Example 3

In Comparative Example 3, Au is used instead of Mo to form a first electrode composed of line-patterned conductive members. The Au thickness is 100 nm, the line width is 4.5 μm, and the gap between lines is 10 μm. Except for these points, the top solar cell is produced by a method similar to that in Example 1, and using the top solar cell, a multi-junction solar cell of Comparative Example 3 is obtained by a method similar to that in Example 1. The solar cell is then evaluated by a method similar to that in Example 1.

When Au is used, it is observed that diffusion of the metal element into the light absorbing layer and to the surface of the light absorbing layer occurs to reduce the aperture ratio significantly. A leak path is formed in the light absorbing layer to reduce the conversion efficiency.

TABLE 1A

| | | | | Top Cell | | |
|---|---|---|---|---|---|---|
| | | | | Conversion | | Transmit- |
| | Voc | Jsc | FF | efficiency | Aperture | tance |
| | ratio | ratio | ratio | ratio | ratio % | ratio |
| Example 1 | 1.14 | 0.95 | 1.17 | 1.26 | 66.7 | — |
| Comparative | | | | | | |
| Example 1 | 0.95 | 1.02 | 0.91 | 0.88 | 100 | — |
| Example 2 | 1.12 | 0.99 | 1.16 | 1.29 | 69.0 | 1.04 |
| Comparative | 1.00 | 1.00 | 1.00 | 1.00 | 69.0 | 1.00 |
| Example 2 | | | | | | |
| Example 3 | 1.12 | 1.01 | 1.15 | 1.30 | 80.0 | — |
| Example 4 | 1.12 | 1.02 | 1.15 | 1.31 | 87.5 | — |
| Example 5 | 1.12 | 0.99 | 1.16 | 1.29 | 69.0 | 1.12 |
| Example 6 | 1.12 | 1.02 | 1.15 | 1.30 | 69.4 | — |
| Example 7 | 1.12 | 1.01 | 1.15 | 1.29 | 82.6 | — |
| Example 8 | 1.12 | 1.02 | 1.14 | 1.31 | 88.9 | — |
| Example 9 | 1.13 | 1.02 | 1.16 | 1.34 | 80.0 | — |
| Example 10 | 1.12 | 0.99 | 1.15 | 1.28 | 69.0 | — |
| Example 11 | 1.07 | 1.00 | 1.15 | 1.23 | 69.0 | — |
| Comparative | 1.07 | 0.98 | 0.86 | 0.90 | 1.01 | — |
| Example 3 | | | | | | |

TABLE 1B

| | | Multi-junction |
|---|---|---|
| | Bottom cell Conversion | solar cell Conversion |
| | efficiency ratio | efficiency ratio |
| Example 1 | 1.00 | 1.13 |
| Comparative | 1.37 | 1.12 |
| Example 1 | | |
| Example 2 | 1.04 | 1.16 |
| Comparative | 1.00 | 1.00 |
| Example 2 | | |
| Example 3 | 1.20 | 1.25 |
| Example 4 | 1.32 | 1.32 |
| Example 5 | 1.12 | 1.20 |
| Example 6 | 1.04 | 1.17 |
| Example 7 | 1.24 | 1.26 |
| Example 8 | 1.34 | 1.32 |
| Example 9 | 1.19 | 1.26 |
| Example 10 | 1.01 | 1.14 |
| Example 11 | 1.04 | 1.13 |
| Comparative | 1.05 | 0.98 |
| Example 3 | | |

Table 1 shows the values relative to those of Comparative Example 2, except for the aperture ratio. All the examples show an increase in Voc. This indicates that the use of a line-patterned or mesh-patterned electrode improves the contact between the light absorbing layer and the first electrode (a line-patterned or mesh-patterned electrode in the examples and a transparent electrode in the comparative examples). The examples also show an increase in FF with no tendency for Jsc to decrease. This indicates that the oxidation is suppressed between the light absorbing layer and the line-patterned or mesh-patterned electrode and the first electrode further improves the current collection efficiency of the electrode. The transmittance ratio is higher in Example 2 than in Comparative Example 2 though the aperture ratio is the same in Example 2 and Comparative Example 2 where the same line electrode is used. This indicates that in Comparative Example 2, the use of carrier-doped (3.4%) ATO to form a transparent electrode on the oxide layer in contact with the line electrode leads to a reduction in infrared transmittance. The difference in infrared transmittance makes a difference in the conversion efficiency of the bottom cell. A combination of the non-doped oxide layer and the line electrode allows even a top cell with the line electrode to have an improved conversion efficiency. Therefore, the multi-junction solar cell having a combination of top and bottom cells has a synergistically improved conversion efficiency. The improvement of the conversion efficiency of the top and bottom cells is observed in all the examples, which means that a combination of a non-doped (up to 2.8% doped) oxide layer and a line-patterned or mesh-patterned electrode according to the embodiment improves the conversion efficiency of both the top and bottom cells.

Here, some elements are expressed only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solar cell comprising:
a high-resistance oxide layer;
a first electrode comprising line-patterned conductive members or mesh-patterned conductive members;
a second electrode; and
a light absorbing layer between the high-resistance oxide layer and the second electrode, wherein the first electrode is disposed between the high-resistance oxide layer and the light absorbing layer.

2. The cell according to claim 1, wherein the line-patterned conductive members or mesh-patterned conductive members are in direct contact with the light absorbing layer.

3. The cell according to claim 1, wherein the high-resistance oxide layer has a total concentration of Sb and F dopants of 0.0 at % to 2.8 at %.

4. The cell according to claim 1, wherein the first electrode has an aperture ratio of 50% to 99% for the high-resistance oxide layer.

5. The cell according to claim 1, wherein the line-patterned conductive members or mesh-patterned conductive members comprise at least one selected from the group consisting of: a metal, an alloy, a conductive oxide, and a conductive nitride.

6. The cell according to claim 1, further comprising a first insulating film between gaps of the line-patterned conductive members or mesh-patterned conductive members.

7. The cell according to claim 1, further comprising a second insulating film between the line-patterned conductive members or mesh-patterned conductive members and the oxide layer.

8. The cell according to claim 1, wherein the line-patterned conductive members or mesh-patterned conductive members comprises at least one metal selected from the group consisting of: Mo, Ru, Rh, Pd, Ag, Ir, and Pt or at least one conductive oxide selected from the group consisting of: RuO₂, PdO, Rh₂O₃, PtO₂, and IrO₂.

9. The cell according to claim 1, wherein the line-patterned conductive members or mesh-patterned conductive members have a width of 30 nm to 10 μm.

10. The cell according to claim 1, wherein the line-patterned conductive members or mesh-patterned conductive members have a height of 10 nm to 50 μm.

11. The cell according to claim 1, wherein the line-patterned conductive members or mesh-patterned conductive member has a gap of 10 nm to 100 μm.

12. The cell according to claim 1, wherein the line-patterned conductive members or mesh-patterned conductive members are uniform in arrangement.

13. The cell according to claim 1, wherein the high-resistance oxide layer has a total concentration of Sb and F dopants of 0.0 at % to 2.5 at %.

14. The cell according to claim 1, wherein the high-resistance oxide layer has a total concentration of Sb and F dopants of 0.0 at % to 2.0 at %.

15. The cell according to claim 1, wherein the first electrode has an aperture ratio of 80% to 99% for the high-resistance oxide layer.

16. A multi-junction solar cell comprising the solar cell according to claim 1.

17. A solar cell module comprising the solar cell according to claim 1.

18. A solar cell module comprising the multi-junction solar cell according to claim 16.

19. A solar power generation system comprising the solar cell module according to claim 17.

20. A solar power generation system comprising the solar cell module according to claim 18.
